(19) United States
(12) Patent Application Publication
(10) Pub. No.: US 2020/0031242 A1
(43) Pub. Date: Jan. 30, 2020

(54) THERMOELECTRIC MODULE WITH THERMAL ISOLATION FEATURES FOR VEHICLE BATTERY

(71) Applicant: GENTHERM INC., Northville, MI (US)

(72) Inventors: David Scott Thomas, Royal Oak, MI (US); Martin Adldinger, Holzheim (DE); Shaun Peter McBride, Augsburg (DE); Dumitru-Cristian Leu, Freising (DE); Rüdiger Spillner, Augsburg (DE)

(21) Appl. No.: 15/580,467

(22) PCT Filed: Jun. 8, 2016
(86) PCT No.: PCT/US2016/036390

§ 371 Date: Dec. 7, 2017

Related U.S. Application Data
(60) Provisional application No. 62/173,446, filed on Jun. 10, 2015.

(51) Int. Cl. B60L 50/64; H01M 10/6572; H01L 23/38; H01L 35/30; F25B 21/02; B60L 58/26; B60L 58/27

(52) U.S. Cl. CPC B60L 50/64; H01M 10/6572; H01L 23/38; H01L 35/30; H01M 2220/20; B60L 58/26; B60L 58/27; B60L 2240/545; F25B 21/02

(57) ABSTRACT

A thermoelectric module assembly for thermally conditioning a component includes first and second heat spreaders that are spaced apart from one another and configured to respectively provide cold and hot sides. An insulator plate is arranged between the first and second heat spreaders. The insulator plate has a compression limiter. A thermoelectric device is arranged with—in the insulator plate and operatively engaged with the first and second heat spreaders. A fastening element secures the first and second heat spreaders to one another about the insulator plate in an assembled condition. The compression limiters are configured to maintain a predetermined spacing between the first and second heat spreaders in the assembled condition.

### CROSS-REFERENCE TO RELATED APPLICATIONS

This application claims priority to U.S. Provisional Application No. 62/173,446, which was filed on Jun. 10, 2015 and is incorporated herein by reference.

### BACKGROUND

This disclosure relates to a thermoelectric module used to cool a vehicle component, such as a battery. In particular, the disclosure relates to thermal isolation features within the thermoelectric module to improve heat transfer efficiency.

Lithium ion batteries are used in passenger and other types of vehicles to provide power to electric motors that provide propulsion to the vehicle. Such batteries can generate a significant amount of heat such that the battery must be cooled to prevent performance degradation.

One type of vehicle battery cooling arrangement that has been proposed that includes a thermoelectric module arranged beneath the battery and adjacent to a cold plate assembly. The thermoelectric module includes thermoelectric devices that operate based upon the Peltier effect to provide cooling adjacent to the battery. Heat transferred through the thermoelectric device is rejected to the cold plate assembly, which may have a cooling fluid circulated therethrough and sent to a heat exchanger.

It is desirable to design the thermoelectric module so as to efficiently transfer heat through some components within the thermoelectric module while insulating other components within the thermoelectric module.

### SUMMARY

In one exemplary embodiment, a thermoelectric module assembly for thermally conditioning a component includes first and second heat spreaders that are spaced apart from one another and configured to respectively provide cold and hot sides. An insulator plate is arranged between the first and second heat spreaders. The insulator plate has a compression limiter. A thermoelectric device is arranged within the insulator plate and operatively engaged with the first and second heat spreaders. A fastening element secures the first and second heat spreaders to one another about the insulator plate in an assembled condition. The compression limiters are configured to maintain a predetermined spacing between the first and second heat spreaders in the assembled condition.

In a further embodiment of any of the above, the first and second heat spreaders are metallic and the insulator plate is a plastic.

In a further embodiment of any of the above, the thermoelectric device is a Peltier device.

In a further embodiment of any of the above, the second heat spreader includes a raised pad that supports the thermoelectric device. The compression limiter is arranged adjacent to the pad.

In a further embodiment of any of the above, a thermal foil is arranged between and in engagement with the pad and the thermoelectric device.

In a further embodiment of any of the above, the second heat spreader includes a protrusion that cooperates with the compression limiter to laterally locate the insulator plate and the second heat spreader relative to one another.

In a further embodiment of any of the above, the fastening element is a threaded fastener secured to a threaded inner diameter of the protrusion. The protrusion is received within the compression limiter.

In a further embodiment of any of the above, the insulator plate has at least four discrete compression limiters that surround the thermoelectric device. The compression limiters engage the first and second heat spreaders.

In another exemplary embodiment, a thermoelectric module assembly for thermally conditioning a component including first and second heat spreaders spaced apart from one another and configured to respectively provide cold and hot sides. An insulator plate is arranged between the first and second heat spreaders. A thermoelectric device is arranged within the insulator plate and operatively engaged with the first and second heat spreaders. A retainer is provided between the insulator plate and the thermoelectric device. The retainers are configured to carry the thermoelectric device with the insulator plate during an assembly procedure.

In a further embodiment of any of the above, the insulator plate includes an aperture and the thermoelectric device has a perimeter. The retainer is arranged in the aperture and engages the perimeter.

In a further embodiment of any of the above, the retainer is at least one flexible spring element.

In a further embodiment of any of the above, the insulator plate is plastic. At least one flexible spring element is integral with the insulator plate.

In a further embodiment of any of the above, the retainer is deflectable in a direction that extends between the first and second heat spreaders to accommodate a desired loaded condition of the thermoelectric device.

In a further embodiment of any of the above, the retainer and a perimeter structure of the thermoelectric device include locating features to locate the thermoelectric device relative to the insulator plate.

In another exemplary embodiment, a thermoelectric module assembly for thermally conditioning a component includes first and second heat spreaders spaced apart from one another and configured to respectively provide cold and hot sides. An insulator plate is arranged between the first and second heat spreaders. A thermoelectric device is arranged within the insulator plate and operatively engaged with the first and second heat spreaders. The thermoelectric device includes a wire. Channels are provided in the insulator plate that receive the wire.

In a further embodiment of any of the above, there are multiple thermoelectric devices. The thermoelectric devices are Peltier devices.

In a further embodiment of any of the above, the insulator plate includes multiple apertures. Each aperture receives a thermoelectric device. The channel interconnects the apertures. The Peltier devices are connected in series to one another.

In another exemplary embodiment, a thermoelectric module assembly for thermally conditioning a component includes first and second heat spreaders spaced apart from one another and configured to respectively provide cold and hot sides. An insulator plate is arranged between the first and second heat spreaders. A thermoelectric device is arranged within the insulator plate and operatively engaged with the first and second heat spreader. A matrix of voids provided in the insulator plate are configured to reduce a thermal mass of the assembly.

In a further embodiment of any of the above, the insulator plate includes a compression limiter that engages the first and second heat spreaders. A channel receives a wire of the thermoelectric device and an aperture within which the thermoelectric device is arranged. The voids are different than the compression limiter, the channel and the aperture.

In a further embodiment of any of the above, the voids are recessed into one side of the insulator plate. The voids do not extend through to an opposing side of the insulator plate.

### BRIEF DESCRIPTION OF THE DRAWINGS

The disclosure can be further understood by reference to the following detailed description when considered in connection with the accompanying drawings wherein:

FIG. 1A is a highly schematic view of a vehicle with a vehicle system temperature regulated by a cooling system.

FIG. 1B illustrates a cooling system that includes a thermoelectric module assembly and a cold plate assembly.

FIG. 2 is an exploded perspective view of a thermoelectric module assembly.

FIG. 3A is a perspective view of an insulator plate.

FIG. 3B is a top elevational view of the insulator plate from FIG. 3A.

FIG. 3C is an enlarged cross-sectional view of a retainer cooperating with a thermoelectric device.

FIG. 4A is a perspective view of the insulator plate mounted to a heat spreader.

FIG. 4B is a perspective view of the insulator plate and heat spreader shown in FIG. 4A with thermoelectric devices arranged within the insulator plate.

FIG. 5A is a perspective view of the thermoelectric module assembly.

FIG. 5B is a cross-sectional view through the thermoelectric module assembly shown in FIG. 5A and taken along line 5B-5B.

FIG. 5C is an enlarged cross-sectional view of a portion of a thermoelectric module assembly illustrated in FIG. 5B and shown as area FIG. 5C.

The embodiments, examples and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

### DETAILED DESCRIPTION

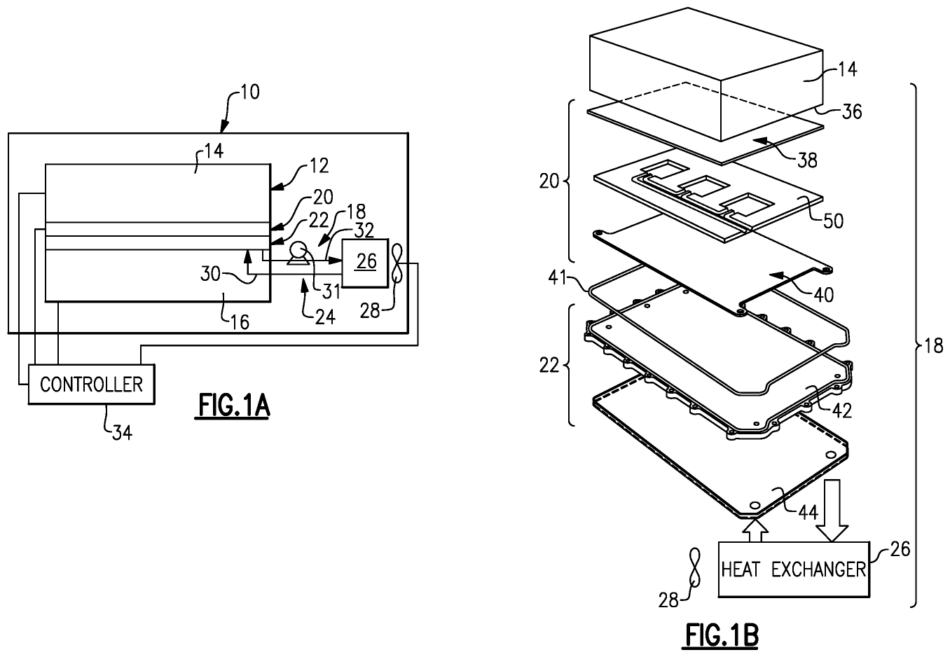

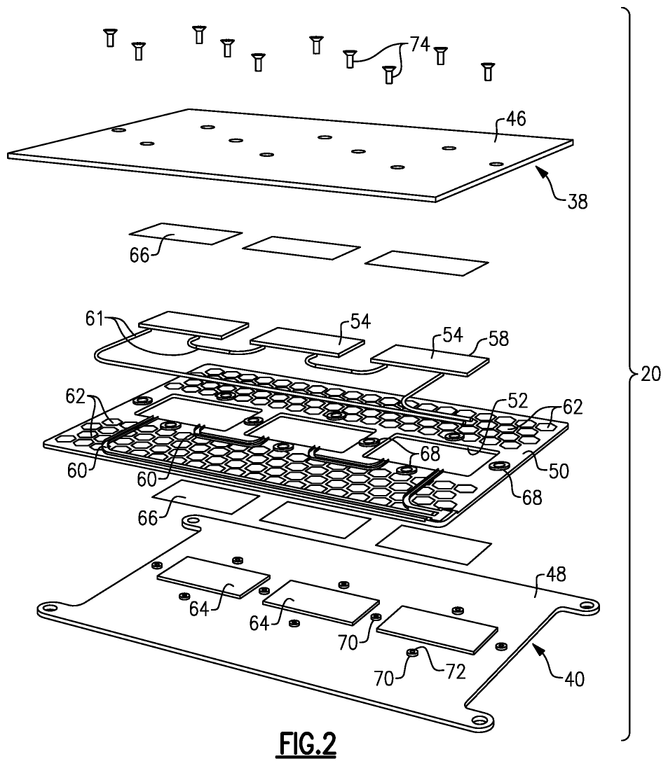

A vehicle 10 is schematically illustrated in FIG. 1A. The vehicle 10 includes a vehicle system 12 that either needs to be heated or cooled. In one example, the vehicle system 12 includes a battery 14, such as a lithium ion battery used for vehicle propulsion that generates a significant amount of heat. Such a battery must be cooled during operation otherwise the battery efficiency and/or integrity may degrade.

A cooling system 18 is arranged between the battery 14 and a DC/DC converter 16 in a stack to remove heat from the battery 14 thus cooling the vehicle system 12. The DC/DC converter 16 provides an electrical interface between the battery 14 and the vehicle electrics. A cooling system 18 includes a thermoelectric module assembly 20 mounted to a cold plate assembly 22 that is in communication with a cooling loop 24. A cooling fluid, such as glycol, is circulated by a pump 31 within the cooling loop 24. Heat is rejected to the coolant via the cold plate assembly 22 through supply and return coolant lines 30, 32 that are connected to a heat exchanger 26. A fan or blower 28 may be used to remove heat from the coolant within the heat exchanger 26 to an ambient environment, for example.

A controller 34 communicates with various components of the vehicle 10, vehicle system 12 and cooling system 18 to coordinate battery cooling. Sensors and outputs (not shown) may be connected to the controller 34.

An example cooling system 18 is shown in more detail in FIG. 1B. The thermoelectric module assembly 20 includes a cold side 38 that supports a surface 36 of the battery 14. An insulator plate 50, which is constructed from a plastic, carries thermoelectric devices (shown at 58 in FIG. 2) and separates the cold side 38 (at the battery 14) from a hot side 40 (at the cold plate assembly 22).

The cold plate assembly 22 includes first and second cold plates 42, 44 secured to one another to enclose a network of fluid passages (not shown) that communicate coolant across the cold plate assembly 22 to receive heat rejected from the hot side 40. A seal 41 may be provided between the thermoelectric module assembly 20 and the cold plate assembly 22. The heated coolant is transferred to the heat exchanger 26, which may be located remotely from the stack.

Referring to FIG. 2, an example thermoelectric module assembly 20 is shown in more detail. The cold and hot sides 38, 40 are respectively provided by first and second heat spreaders 46, 48, which are constructed from metal. The insulator plate 50 is sandwiched between the first and second heat spreaders 46, 48 once assembled into a single unit that can be secured to the cold plate assembly 22.

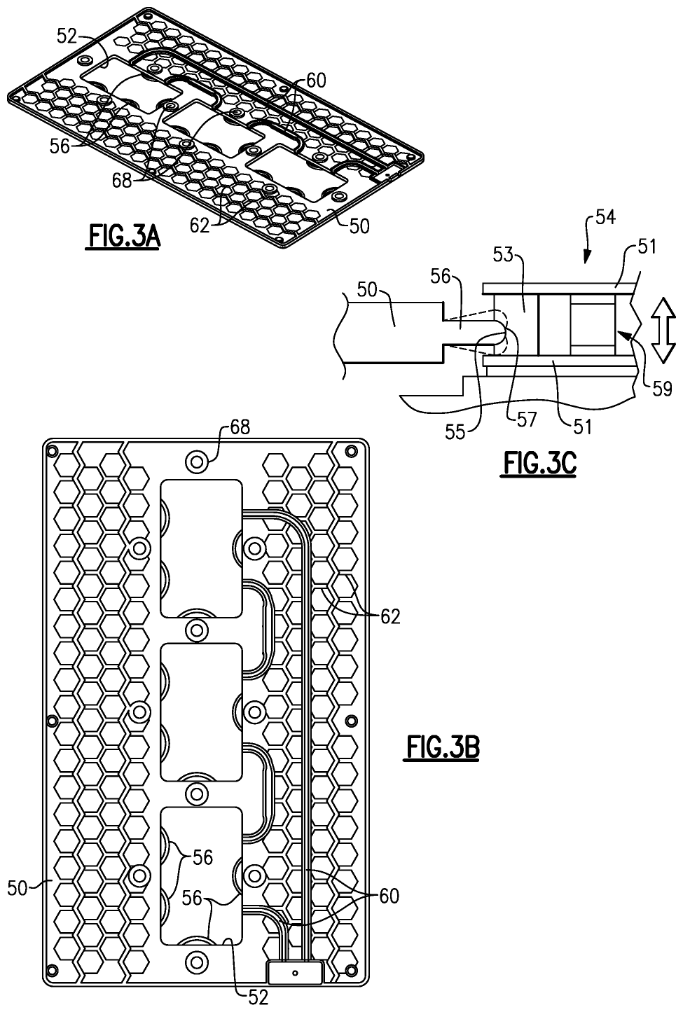

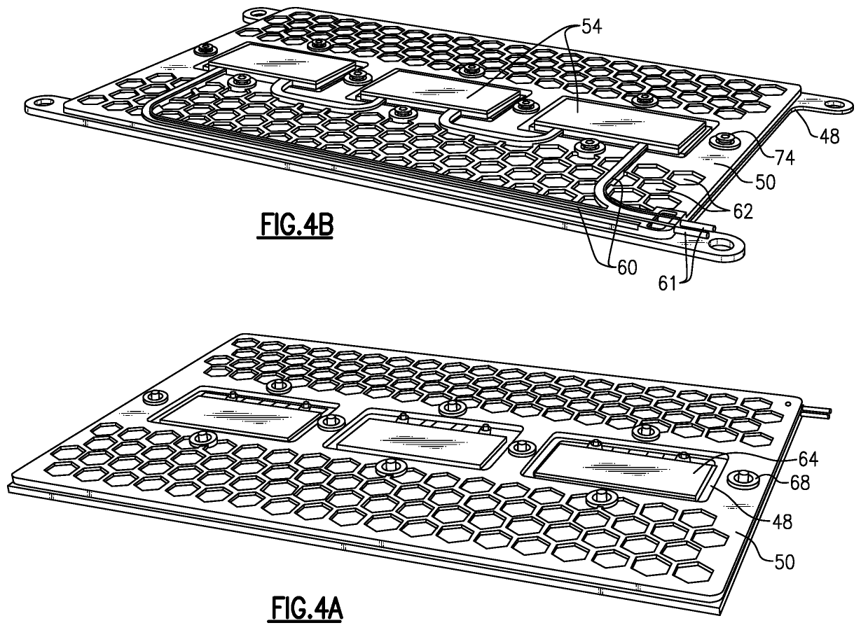

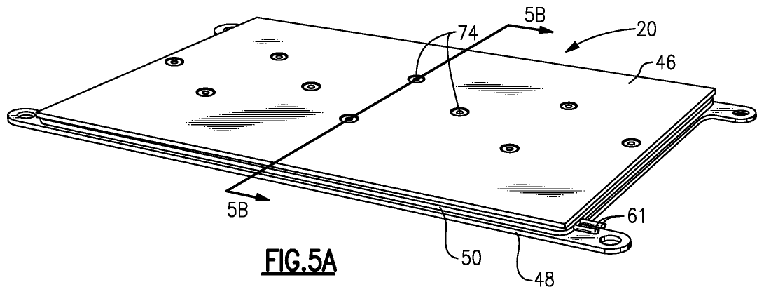

The insulator plate 50 includes apertures 52 within which thermoelectric devices 54 are arranged. In the example, the thermoelectric devices utilize the Peltier effect to provide a cold side adjacent to the first heat spreader 46 and a hot side adjacent to the second heat spreader 48. Retainers 56, best shown in FIGS. 3A-3C, are arranged within the apertures 52 and cooperate with a perimeter 58 of the thermoelectric device to securely carry the thermoelectric devices 54 during assembly of the thermoelectric module assembly 20. The retainers 56 are flexible spring elements provided integrally with the insulator plate 50, which may be injection molded as a unitary structure. In the example, the retainers 56 are arcuate in shape and have a thickness that is less than the thickness of the insulator plate 50 to provide improved flexibility.

One example thermoelectric device 54 includes plates 51 engaging a p-n assembly 59. A perimeter structure 53, which may be an elastic material, for example, is arranged between the plates 51 near an outer boundary of the thermoelectric device 54. The retainer 56, which may have a rounded profile 57, cooperates with a recess 55 in the perimeter structure 53 to provide a locating feature that positively locates and retains the thermoelectric device 54 within the insulator plate 50. In addition to the retainer 56 being deflectable inward and away from the thermoelectric device 54 during assembly, the retainer 56 is also deflectable in the directions of the arrow to accommodate movement of the thermoelectric device 54 when clamped between the heat spreaders 46, 48 in a desired loaded condition.

Insulator plate 50 includes formed wire channels 60 that receive wires 61 of the thermoelectric devices 54 of the thermoelectric module assembly 20. In the example, three Peltier devices are wired in series with one another.

A matrix of voids 62 is provided in the insulator plate 50 to reduce the thermal mass of the insulator plate 50 and provide air gaps that insulate the first and second heat spreaders 46, 48 from one another. The voids 62 may be any suitable size, shape or pattern. The voids may be deep recesses relative to the thickness of the insulator plate 50 (shown) or extend all the way through the insulator plate 50.

The second heat spreader 48 includes raised pads 64 that extend upward toward the insulator plate 50 to support the thermoelectric devices 54. Thermal interface material 66 may be provided between the thermoelectric devices 54 and the first and second heat spreaders 46, 48 to ensure adequate engagement between the components for thermal efficiency. In this example a thermal foil is used.

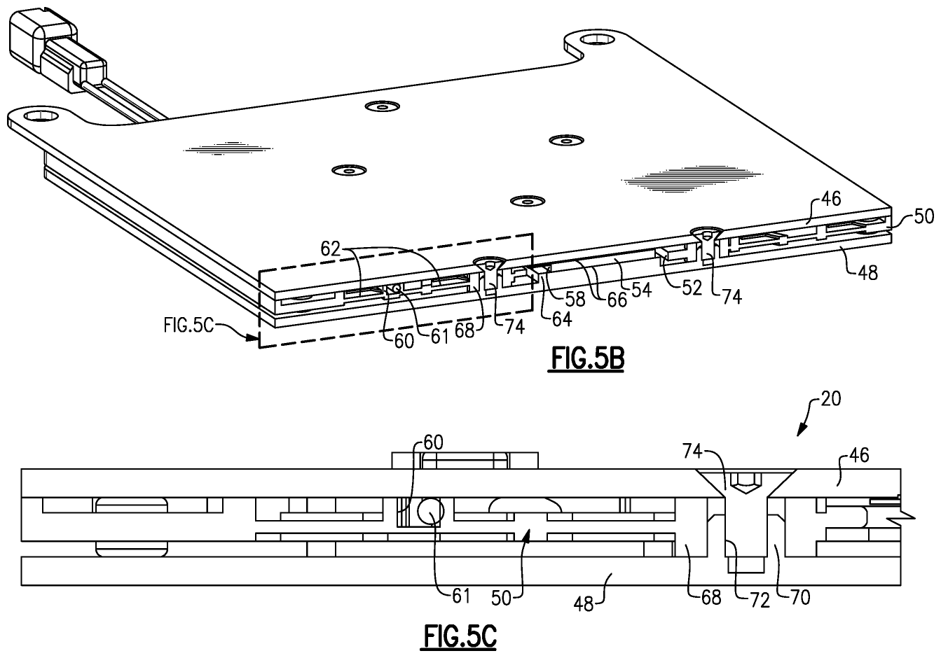

Referring to FIGS. 2 and 5A-5C, the insulator plate 50 includes spacers 68, which define the spacing between the first and second heat spreaders 46, 48 during assembly and act as compression limiters. The spacers 68 are integral with the insulator plate 50 in the example. In the example, a spacer 68 is provided as raised portions on each side of the thermoelectric device 54 to prevent the weight of the battery 14 on the thermoelectric module assembly 20 from applying an undesirably high load on the thermoelectric device 54, which could be detrimental to its operation. Thus, the height of the spacers 68 take into account the tolerance stack-up of the components between the first and second heat spreaders 46, 48 while ensuring desired thermal engagement through thermoelectric stack.

Protrusions 70 may be provided on, for example, the second heat spreader 48 to locate the insulator plate 50 relative to the second heat spreader 48 during assembly. In the example, fasteners 74 extend through holes in the first heat spreader 46 and are received within threaded inner diameters 72 of the protrusions 70 to secure the stack of first and second heat spreaders 46, 48 and the insulator plate 50. The spacers 68 and protrusions 70 circumscribe their respective fastener 74 in the example, but the spacers 68 could be located elsewhere or configured differently than shown. The fasteners 74 are tightened to a predetermined torque, and the spacers 68 limit the travel of the heat spreaders relative to one another as the fasteners are torqued.

In operation, an undesired battery temperature is detected by the controller 34. The thermoelectric devices 50 are powered to produce a cold side of the thermoelectric device 54 that is transferred to the first heat spreader 46 adjacent to the battery 14 increasing the temperature differential between these components and increasing the heat transfer therebetween. Heat from the battery is transferred from the first heat spreader 46 through the thermoelectric device 54 to the second heat spreader 48. However, the isolator plate 50 acts to prevent heat from being transmitted from the first heat spreader 46 to the second heat spreader 48. The second heat spreader 48 rejects heat to the coolant within the cold plate assembly 22. Coolant is circulated from the cold plate assembly 22 to the heat exchanger 26, which rejects heat to the ambient environment, and this heat transfer rate may be increased by use of the blower 28.

It should be understood that although a particular component arrangement is disclosed in the illustrated embodiment, other arrangements will benefit herefrom. Although particular step sequences are shown, described, and claimed, it also should be understood that steps may be performed in any order, separated or combined unless otherwise indicated and will still benefit from the present invention.

Although the different examples have specific components shown in the illustrations, embodiments of this invention are not limited to those particular combinations. It is possible to use some of the components or features from one of the examples in combination with features or components from another one of the examples.

Although an example embodiment has been disclosed, a worker of ordinary skill in this art would recognize that certain modifications would come within the scope of the claims. For that reason, the following claims should be studied to determine their true scope and content.

What is claimed is:

1. A thermoelectric module assembly for thermally conditioning a component, the assembly comprising:
first and second heat spreaders spaced apart from one another and configured to respectively provide cold and hot sides;
an insulator plate arranged between the first and second heat spreaders, the insulator plate has a compression limiter;
a thermoelectric device arranged within the insulator plate and operatively engaged with the first and second heat spreaders; and
a fastening element securing the first and second heat spreaders to one another about the insulator plate in an assembled condition, the compression limiters configured to maintain a predetermined spacing between the first and second heat spreaders in the assembled condition.

2. The assembly according to claim 1, wherein the first and second heat spreaders are metallic and the insulator plate is a plastic.

3. The assembly according to claim 1, wherein the thermoelectric device is a Peltier device.

4. The assembly according to claim 1, wherein the second heat spreader includes a raised pad supporting the thermoelectric device, and the compression limiter is arranged adjacent to the pad.

5. The assembly according to claim 4, comprising a thermal foil arranged between and in engagement with the pad and the thermoelectric device.

6. The assembly according to claim 1, the second heat spreader includes a protrusion that cooperates with the compression limiter to laterally locate the insulator plate and the second heat spreader relative to one another.

7. The assembly according to claim 6, wherein the fastening element is a threaded fastener secured to a threaded inner diameter of the protrusion, the protrusion received within the compression limiter.

8. The assembly according to claim 1, wherein the insulator plate has at least four discrete compression limiters that surround the thermoelectric device, the compression limiters engage the first and second heat spreaders.

9. A thermoelectric module assembly for thermally conditioning a component, the assembly comprising:
first and second heat spreaders spaced apart from one another and configured to respectively provide cold and hot sides;
an insulator plate arranged between the first and second heat spreaders;
a thermoelectric device arranged within the insulator plate and operatively engaged with the first and second heat spreaders; and
a retainer provided between the insulator plate and the thermoelectric device, the retainers configured to carry the thermoelectric device with the insulator plate during an assembly procedure.

10. The assembly according to claim 9, wherein the insulator plate includes an aperture, and the thermoelectric device has a perimeter, the retainer arranged in the aperture and engages the perimeter.

11. The assembly according to claim 10, wherein the retainer is at least one flexible spring element.

12. The assembly according to claim 11, wherein the insulator plate is plastic, and the at least one flexible spring element is integral with the insulator plate.

13. The assembly according to claim 11, wherein the retainer is deflectable in a direction that extends between the first and second heat spreaders to accommodate a desired loaded condition of the thermoelectric device.

14. The assembly according to claim 11, wherein the retainer and a perimeter structure of the thermoelectric device include locating features to locate the thermoelectric device relative to the insulator plate.

15. A thermoelectric module assembly for thermally conditioning a component, the assembly comprising:
first and second heat spreaders spaced apart from one another and configured to respectively provide cold and hot sides;
an insulator plate arranged between the first and second heat spreaders;
a thermoelectric device arranged within the insulator plate and operatively engaged with the first and second heat spreaders, the thermoelectric device includes a wire; and
channels provided in the insulator plate that receive the wire.

16. The assembly according to claim 15, comprising multiple thermoelectric devices, the thermoelectric devices are Peltier devices.

17. The assembly according to claim 15, wherein the insulator plate includes multiple apertures, each aperture receiving a thermoelectric device, and the channel interconnecting apertures, the Peltier devices are connected in series to one another.

18. A thermoelectric module assembly for thermally conditioning a component, the assembly comprising:
first and second heat spreaders spaced apart from one another and configured to respectively provide cold and hot sides;
an insulator plate arranged between the first and second heat spreaders;
a thermoelectric device arranged within the insulator plate and operatively engaged with the first and second heat spreader; and
a matrix of voids provided in the insulator plate configured to reduce a thermal mass of the assembly.

19. The assembly according to claim 18, wherein the insulator plate includes a compression limiter engaging the first and second heat spreaders, a channel receiving a wire of the thermoelectric device, and an aperture within which the thermoelectric device is arranged, the voids different than the compression limiter, the channel and the aperture.

20. The assembly according to claim 18, wherein the voids are recessed into one side of the insulator plate, but the voids do not extend through to an opposing side of the insulator plate.
